(19) United States
(12) Patent Application Publication
(10) Pub. No.: US 2024/0395336 A1
(43) Pub. Date: Nov. 28, 2024

(54) MEMORY DEVICE FOR DRIVING CHARGE PUMPS RESPECTIVELY INCLUDED IN MEMORY DIES

(71) Applicant: SK hynix Inc., Icheon-si Gyeonggi-do (KR)

(72) Inventors: Won Jae CHOI, Icheon-si Gyeonggi-do (KR); Ji Hoon LIM, Icheon-si Gyeonggi-do (KR)

(73) Assignee: SK hynix Inc., Icheon-si Gyeonggi-do (KR)

(21) Appl. No.: 18/496,735

(22) Filed: Oct. 27, 2023

(30) Foreign Application Priority Data
May 24, 2023 (KR) 10-2023-0066925

(51) Int. Cl. G11C 16/30; G11C 16/08; G11C 16/32

(52) U.S. Cl. CPC G11C 16/30; G11C 16/08; G11C 16/32

(57) ABSTRACT

Provided herein is a memory device for driving charge pumps respectively included in memory dies. The memory device includes a first memory die including a first charge pump and a first pump control circuit, and a second memory die including a second charge pump coupled to the first charge pump through a pump line and a second pump control circuit coupled to the first pump control circuit through a control line. The first pump control circuit is configured to control the first charge pump to perform a pump operation of generating a pump voltage in response to a command received by the first memory die, and output an operation alarm signal through the control line, and the second pump control circuit is configured to control the second charge pump to perform the pump operation in response to the operation alarm signal.

### CROSS-REFERENCE TO RELATED APPLICATION

The present application claims priority under 35 U.S.C. § 119(a) to Korean patent application number 10-2023-0066925 filed on May 24, 2023, in the Korean Intellectual Property Office, the entire disclosure of which is incorporated by reference herein.

### BACKGROUND

### 1. Technical Field

Various embodiments of the present disclosure generally relate to an electronic device, and more particularly, to a memory device for driving charge pumps respectively included in memory dies.

### 2. Related Art

A memory system is a device which stores data under the control of a host device such as a computer or a smartphone. The memory system may include a memory device in which data is stored and a memory controller which controls the memory device. Memory devices are classified into a volatile memory device and a nonvolatile memory device.

The nonvolatile memory device may be a memory device in which stored data is retained even when the supply of power is interrupted. Examples of the nonvolatile memory device may include a read only memory (ROM), a programmable ROM (PROM), an electrically programmable ROM (EPROM), an electrically erasable and programmable ROM (EEPROM), and a flash memory.

Such a memory device may include a plurality of memory dies. Each memory die may independently perform an operation corresponding to a command from the memory controller in response to the command. Any one of the plurality of memory dies may generate an operating voltage used to perform the operation corresponding to the command in response to the command. Any one memory die may store data in memory cells or read data stored in the memory cells by applying the operating voltage to the memory cells. Among the plurality of memory dies, the remaining memory dies may perform no operations unless a command is received.

### SUMMARY

An embodiment of the present disclosure may provide for a memory device. The memory device may include a first memory die including a first charge pump and a first pump control circuit, and a second memory die including a second charge pump coupled to the first charge pump through a pump line and a second pump control circuit coupled to the first pump control circuit through a control line. The first pump control circuit may be configured to control the first charge pump to perform a pump operation of generating a pump voltage in response to a command received by the first memory die, and may be configured to output an operation alarm signal through the control line, and the second pump control circuit may be configured to control the second charge pump to perform the pump operation in response to the operation alarm signal.

An embodiment of the present disclosure may provide for a memory device. The memory device may include a first memory die including a first pump control circuit, a first charge pump, and a first regulator, and a second memory die including a second pump control circuit coupled in common to the first pump control circuit, a second charge pump, and a second regulator coupled in common to the first regulator. The first pump control circuit may drive the first charge pump based on a pump enable signal activated in response to a command received by the first memory die and output an operation alarm signal, indicating that the first charge pump is operating, to the second pump control circuit, and the second pump control circuit may drive the second charge pump in response to the operation alarm signal.

An embodiment of the present disclosure may provide for a memory device. The memory device may include a plurality of charge pumps coupled to each other in common through a pump line, and a plurality of pump control circuits coupled to each other in common through a control line, and configured to control respective pump operations of the plurality of charge pumps. A first pump control circuit among the plurality of pump control circuits may control a first charge pump among the plurality of charge pumps to perform the pump operation in response to a pump enable signal, and may output an operation alarm signal to the control line, and remaining pump control circuits among the plurality of pump control circuits may control remaining charge pumps among the plurality of charge pumps to perform respective pump operations in response to the operation alarm signal. The plurality of charge pumps and the plurality of pump control circuits may be included in different memory dies, respectively.

### BRIEF DESCRIPTION OF THE DRAWINGS

FIG. 1 is a diagram illustrating a memory system including a memory device according to an embodiment of the present disclosure.

FIG. 2 is a diagram illustrating a pump control circuit.

FIG. 3 is a diagram illustrating a charge pump.

FIG. 4 is a diagram illustrating the operation of a first pump control circuit and a first charge pump.

FIG. 5 is a diagram illustrating the operation of a second pump control circuit and a second charge pump.

FIG. 6 is a diagram illustrating a plurality of memory dies, each including a pump control circuit, a charge pump, and a regulator.

FIG. 7 is a diagram illustrating any one of a plurality of memory dies.

FIG. 8 is a flowchart illustrating a pump operation performed by a plurality of charge pumps.

### DETAILED DESCRIPTION

Specific structural or functional descriptions in the embodiments of the present disclosure introduced in this specification or application are only for description of the embodiments of the present disclosure. The descriptions should not be construed as being limited to the embodiments described in the specification or application.

Various embodiments of the present disclosure are directed to a memory device for driving charge pumps having a reduced area.

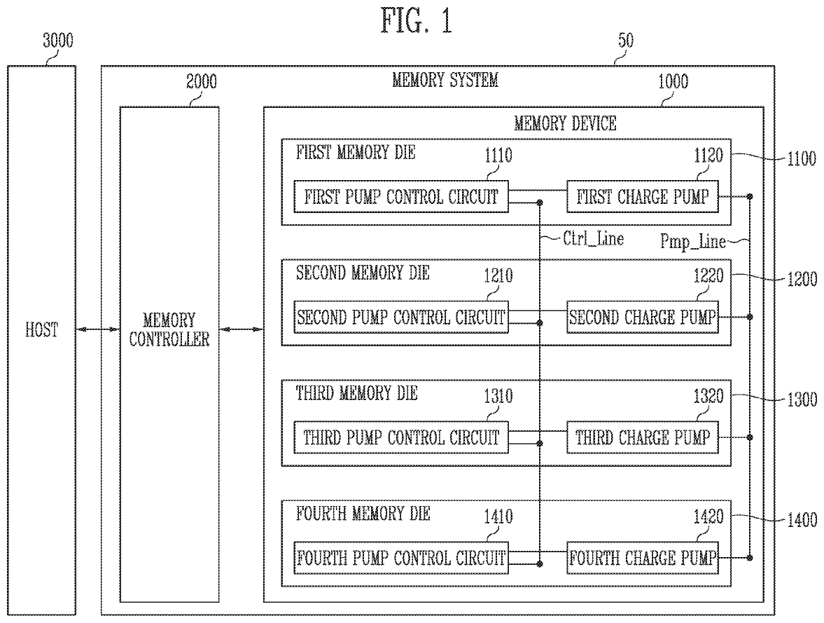

FIG. 1 is a diagram illustrating a memory system including a memory device according to an embodiment of the present disclosure.

Referring to FIG. 1, a memory system 50 may include a memory device 1000 and a memory controller 2000. The memory system 50 may be a device that is included in a mobile phone, a computer, an in-vehicle infotainment system, or the like and that stores data under the control of a host 3000 which is an external device.

The memory system 50 may be manufactured as various types of storage devices such as a solid state drive (SSD) and a universal flash storage (UFS) depending on a host interface that is a scheme for communication with the host 3000. The memory system 50 may be manufactured in various types of package forms such as a system-on-chip (SOC).

The memory device 1000 may store data. The memory device 1000 may be operated under the control of the memory controller 2000. In an embodiment, the memory device 1000 may be a nonvolatile memory device or a volatile memory device.

The memory device 1000 may receive a command and an address from the memory controller 2000, and may perform an operation indicated by the command on an area selected by the address. The memory device 1000 may perform a program operation (write operation) of storing data in the area selected by the address, a read operation of reading data, or an erase operation of erasing data.

The memory controller 2000 may control the overall operation of the memory system 50.

When power is applied to the memory system 50, the memory controller 2000 may run firmware (FW). In an embodiment, the memory controller 2000 may control communication between the host 3000 and the memory device 1000 by running the firmware. In an embodiment, the memory controller 2000 may translate a logical address of the host into a physical address of the memory device.

The memory controller 2000 may control the memory device 1000 so that a program operation, a read operation or an erase operation is performed in response to a request received from the host 3000. The memory controller 2000 may provide a command, a physical address, or data to the memory device 1000 depending on the write operation, the read operation or the erase operation.

In an embodiment, the memory controller 2000 may internally generate a command, an address, and data regardless of whether a request from the host 3000 is received, and may transmit them to the memory device 1000. For example, the memory controller 2000 may provide the memory device 1000 with commands, addresses, and data required in order to perform read operations and program operations that are involved in performing wear leveling, read reclaim, garbage collection, etc.

The host 3000 may communicate with the memory system 50 using various communication schemes.

In an embodiment, the memory device 1000 may include a plurality of memory dies. For example, when the memory device 1000 includes four memory dies, the memory device 1000 may include a first memory die 1100, a second memory die 1200, a third memory die 1300, and a fourth memory die 1400. The number of memory dies included in the memory device 1000 may be less than or greater than 4. Each memory die may perform a program operation, a read operation or an erase operation in response to the command received from the memory controller 2000.

The first to fourth memory dies 1100 to 1400 may include first to fourth pump control circuits 1110 to 1410, respectively, and first to fourth charge pumps 1120 to 1420, respectively. The first memory die 1100 may include the first pump control circuit 1110 and the first charge pump 1120, and the second memory die 1200 may include the second pump control circuit 1210 and the second charge pump 1220.

The first to fourth pump control circuits 1110 to 1410 may drive the first to fourth charge pumps 1120 to 1420, respectively. The first to fourth pump control circuits 1110 to 1410 may control the first to fourth charge pumps 1120 to 1420, respectively, to perform a pump operation of generating a pump voltage.

The first to fourth charge pumps 1120 to 1420 may generate the pump voltage under the control of the first to fourth pump control circuits 1110 to 1410. The pump voltage may be a voltage used to perform an operation corresponding to the command.

The first to fourth pump control circuits 1110 to 1410 may be coupled to each other in common through a control line Ctrl_Line. The first to fourth charge pumps 1120 to 1420 may be coupled to each other in common through a pump line Pmp_Line.

The memory controller 2000 may provide the command to any one of the first to fourth memory dies 1100 to 1400. In an embodiment, the memory controller 2000 may provide the command to the first memory die 1100, and the first memory die 1100 may perform an operation corresponding to the command. Because the second to fourth memory dies 1200 to 1400 have received no commands, they may be in an idle state.

The first memory die 1100 having received the command may generate the pump voltage used to perform the operation corresponding to the command. In detail, the first pump control circuit 1110 may control the first charge pump 1120 to perform the pump operation in response to the command. The first pump control circuit 1110 may output an operation alarm signal, indicating that the first charge pump 1120 is operating, through the control line Ctrl_Line. The operation alarm signal may be a bus signal.

The first charge pump 1120 may perform the pump operation under the control of the first pump control circuit 1110. The first charge pump 1120 may output the pump voltage through the pump line Pmp_Line during the pump operation.

The second to fourth pump control circuits 1210 to 1410 may receive the operation alarm signal, output from the first pump control circuit 1110, through the control line Ctrl_Line. The second to fourth pump control circuits 1210 to 1410 may control the second to fourth charge pumps 1220 to 1420 to perform the pump operation in response to the operation alarm signal. That is, although the second to fourth memory dies 1200 to 1400 have received no commands, the second to fourth charge pumps 1220 to 1420 included in the second to fourth memory dies 1200 to 1400, respectively, may perform the pump operation in response to the operation alarm signal.

The second to fourth charge pumps 1220 to 1420 may perform the pump voltage under the control of the second to fourth pump control circuits 1210 to 1410. The second to fourth charge pumps 1220 to 1420 may output the pump voltage through the pump line Pmp_Line during the pump operation.

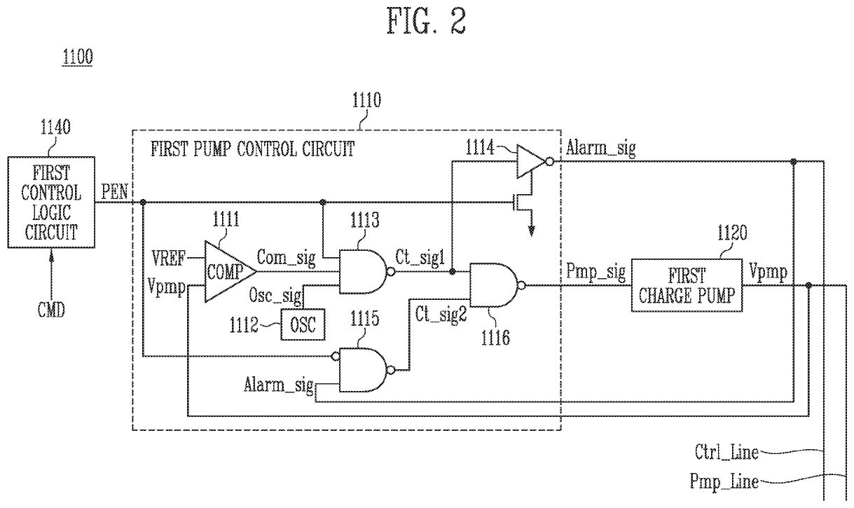

FIG. 2 is a diagram illustrating a pump control circuit.

In FIG. 2, the first pump control circuit 1110 included in the first memory die 1100, illustrated in FIG. 1, will be described by way of example. The second to fourth pump control circuits 1210 to 1410, illustrated in FIG. 1, may be implemented in the same manner as the first pump control circuit 1110 illustrated in FIG. 2.

Referring to FIG. 2, the first memory die 1100 may include the first pump control circuit 1110, the first charge pump 1120, and a first control logic circuit 1140.

The first control logic circuit 1140 may output a pump enable signal PEN to the first pump control circuit 1110 in response to a command CMD received from the memory controller.

In an embodiment, the first control logic circuit 1140 may activate the pump enable signal PEN when the command CMD is received from the memory controller. In an embodiment, the pump enable signal PEN may be a deactivated signal before the command CMD is received from the memory controller. The first control logic circuit 1140 may deactivate the pump enable signal when the command CMD is not received. In FIG. 2, the activated signal may correspond to logic high, and the deactivated signal may correspond to logic low.

The first pump control circuit 1110 may include a comparator 1111, an oscillator 1112, a first gate 1113, a second gate 1114, a third gate 1115, and a fourth gate 1116.

The comparator 1111 may output a comparison signal Com_sig based on the result of comparing a reference voltage VREF with a pump voltage Vpmp received from the first charge pump 1120. In an embodiment, when the reference voltage VREF is higher than the pump voltage Vpmp, the comparator 1111 may activate the comparison signal Com_sig. In an embodiment, when the reference voltage VREF is lower than the pump voltage Vpmp, the comparator 1111 may deactivate the comparison signal Com_sig.

The oscillator 1112 may output an oscillation signal Osc_sig.

The first gate 1113 may output a first control signal Ct_sig1 based on the pump enable signal PEN, the comparison signal Com_sig, and the oscillation signal Osc_sig. In an embodiment, the first gate 1113 may be a NAND gate. The first gate 1113 may activate the first control signal Ct_sig1 when at least one of the pump enable signal PEN, the comparison signal Com_sig, and the oscillation signal Osc_sig is a deactivated signal. The first gate 1113 may deactivate the first control signal Ct_sig1 when all of the pump enable signal PEN, the comparison signal Com_sig, and the oscillation signal Osc_sig are activated signals. The first control signal Ct_sig1 may be output to the second gate 1114 and the fourth gate 1116.

The second gate 1114 may output an operation alarm signal Alarm_sig based on the pump enable signal PEN and the first control signal Ct_sig1. The second gate 1114 may be coupled to a control line Ctrl_Line. The operation alarm signal Alarm_sig may be output through the control line Ctrl_Line. The operation alarm signal Alarm_sig may be output to the third gate 1115.

The second gate 1114 may output an inverted signal of the first control signal Ct_sig1, as the operation alarm signal Alarm_sig, based on the activated pump enable signal. When the deactivated first control signal is received in the state in which the pump enable signal PEN is activated, the second gate 1114 may activate the operation alarm signal Alarm_sig. When the activated first control signal is received in the state in which the pump enable signal PEN is activated, the second gate 1114 may deactivate the operation alarm signal Alarm_sig.

The second gate 1114 may float when the pump enable signal PEN is a deactivated signal. The second gate 1114 might not output the operation alarm signal Alarm_sig in response to the deactivated pump enable signal.

The third gate 1115 may output a second control signal Ct_sig2 based on the pump enable signal PEN and the operation alarm signal Alarm_sig. In an embodiment, the third gate 1115 may be a NAND gate. The third gate 1115 may receive an inverted signal of the pump enable signal PEN. The third gate 1115 may activate the second control signal Ct_sig2 based on the activated pump enable signal and the activated operation alarm signal. The third gate 1115 may activate the second control signal Ct_sig2 based on the activated pump enable signal and the deactivated operation alarm signal. The third gate 1115 may activate the second control signal Ct_sig2 based on the deactivated pump enable signal and the deactivated operation alarm signal. The third gate 1115 may deactivate the second control signal Ct_sig2 based on the deactivated pump enable signal and the activated operation alarm signal.

The fourth gate 1116 may output the pump operation signal Pmp_sig to the first charge pump 1120 based on the first control signal Ct_sig1 and the second control signal Ct_sig2. In an embodiment, the fourth gate 1116 may be a NAND gate. The pump operation signal Pmp_sig may be a signal instructing the first charge pump 1120 to perform a pump operation. The fourth gate 1116 may activate the pump operation signal Pmp_sig when at least one of the first control signal Ct_sig1 and the second control signal Ct_sig2 is a deactivated signal. The fourth gate 1116 may deactivate the pump operation signal Pmp_sig when both the first control signal Ct_sig1 and the second control signal Ct_sig2 are activated signals.

The first charge pump 1120 may generate the pump voltage Vpmp in response to the pump operation signal Pmp_sig. The first charge pump 1120 may be coupled to a pump line Pmp_Line. The pump voltage Vpmp may be output through the pump line Pmp_Line. The pump voltage Vpmp may be output to the comparator 1111.

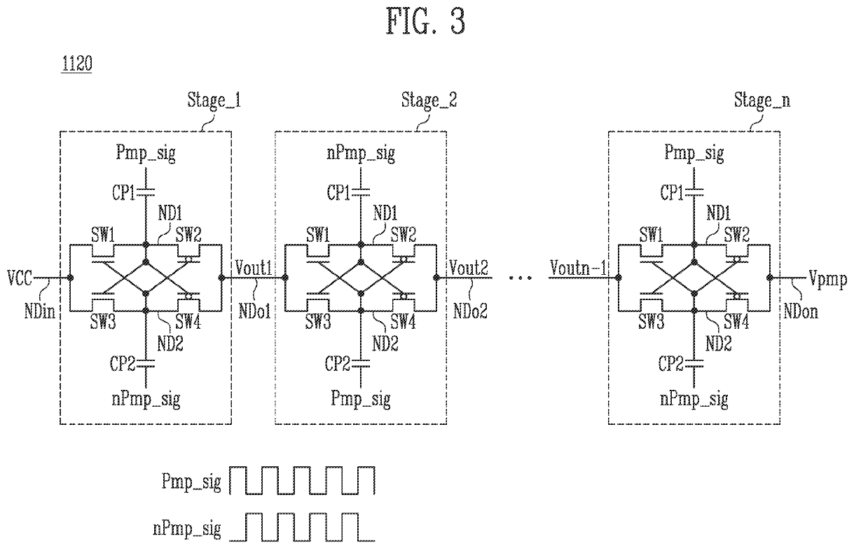

FIG. 3 is a diagram illustrating a charge pump.

In FIG. 3, the first charge pump 1120 included in the first memory die 1100, illustrated in FIG. 1, will be described by way of example. The second to fourth charge pumps 1220 to 1420 illustrated in FIG. 1 may be implemented in the same manner as the first charge pump 1120 illustrated in FIG. 3.

Referring to FIG. 3, the first charge pump 1120 may include first to n-th stages Stage_1 to Stage_n connected in series between an input node NDin and an n-th output node NDon. Each of the first to n-th stages Stage_1 to Stage_n may perform a pump operation in response to the pump operation signal Pmp_sig, received from the first pump control circuit 1110, and an inverted pump operation signal nPmp_sig. In an embodiment, the pump operation signal Pmp_sig may be a clock signal.

In an embodiment, the first stage Stage_1 may include first and second switches SW1 and SW2 and third and fourth switches SW3 and SW4, which are coupled between the input node NDin and the second stage Stage_2. A supply voltage VCC may be applied to the input node NDin.

The first and second switches SW1 and SW2 and the third and fourth switches SW3 and SW4 may be connected in parallel to each other. The first switch SW1 and the second switch SW2 may be connected in series to each other. The third switch SW3 and the fourth switch SW4 may be connected in series to each other. The first switch SW1 and the third switch SW3 may be NMOS transistors. The second switch SW2 and the fourth switch SW4 may be PMOS transistors.

A first capacitor CP1 may be coupled to a first node ND1 between the first switch SW1 and the second switch SW2. The pump operation signal Pmp_sig may be applied to the first capacitor CP1. A second capacitor CP2 may be coupled to a second node ND2 between the third switch SW3 and the fourth switch SW4. The inverted pump operation signal Pmp_sig may be applied to the second capacitor CP2.

In an embodiment, when the pump operation signal Pmp_sig is logic high, the inverted pump operation signal nPmp_sig may be logic low. When the pump operation signal Pmp_sig is logic high, the potential of the first node ND1 may be high. When the potential of the first node ND1 is high, the third switch SW3 coupled to the first node may be turned on, and the fourth switch SW4 may be turned off. The supply voltage VCC applied to the input node NDin may be transferred to the second capacitor CP2 as the third switch SW3 is turned on.

When the inverted pump operation signal nPmp_sig is logic low, the potential of the second node ND2 may be low. When the potential of the second node ND2 is low, the first switch SW1 coupled to the second node may be turned off, and the second switch SW2 may be turned on. Charges stored in the first capacitor CP1 may be transferred to the first output node NDo1 as the second switch SW2 is turned on.

In an embodiment, when the pump operation signal Pmp_sig is logic low, the inverted pump operation signal nPmp_sig may be logic high. When the pump operation signal Pmp_sig is logic low, the potential of the first node ND1 may be low. When the potential of the first node ND1 is low, the third switch SW3 coupled to the first node may be turned off, and the fourth switch SW4 may be turned on. Charges stored in the second capacitor CP2 may be transferred to the first output node NDo1 as the fourth switch SW4 is turned on.

When the inverted pump operation signal nPmp_sig is logic high, the potential of the second node ND2 may be high. When the potential of the second node ND2 is high, the first switch SW1 coupled to the second node may be turned on, and the second switch SW2 may be turned off. The supply voltage VCC applied to the input node NDin may be transferred to the first capacitor CP1 as the first switch SW1 is turned on.

In an embodiment, the first stage Stage_1 may perform a pump operation in response to the pump operation signal Pmp_sig and the inverted pump operation signal nPmp_sig, and may output a first output voltage Vout1 higher than the supply voltage VCC applied to the input node NDin to the first output node NDo1.

The second to n-th stages Stage_2 to Stage_n may be implemented in the same manner as the first stage Stage_1. In an embodiment, the second stage Stage_2 may output a second output voltage Vout2 higher than the first output voltage Vout1 in response to the pump operation signal Pmp_sig and the inverted pump operation signal nPmp_sig. The n-th stage Stage_n may output a pump voltage Vpmp higher than an n−1-th output voltage Voutn−1 in response to the pump operation signal Pmp_sig and the inverted pump operation signal nPmp_sig.

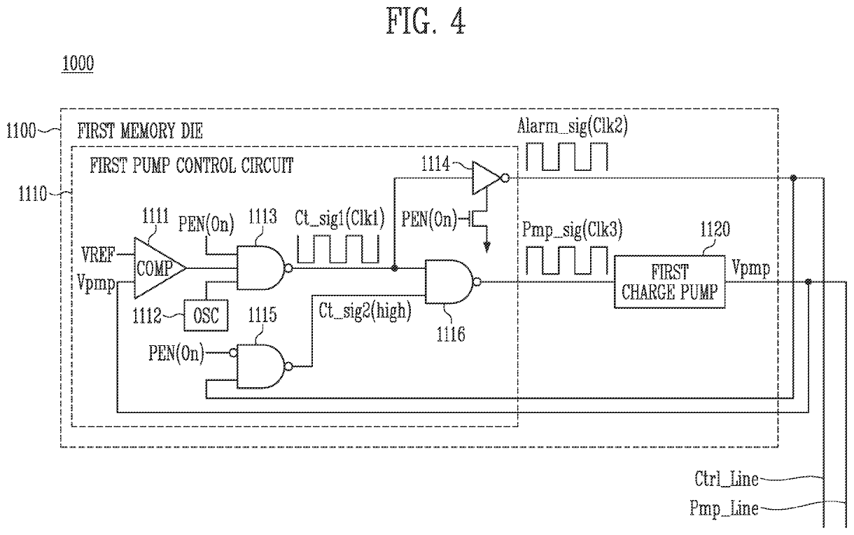

FIG. 4 is a diagram illustrating the operation of a first pump control circuit and a first charge pump.

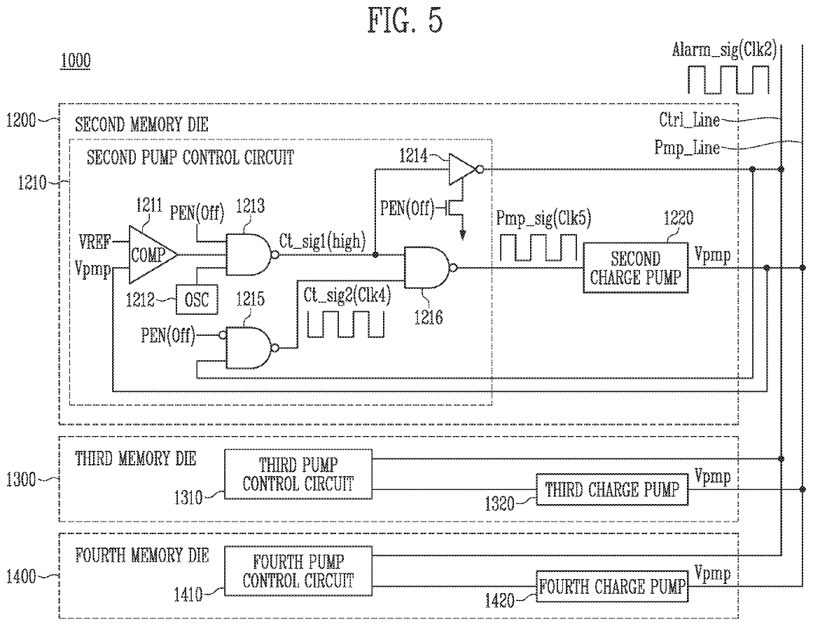

FIG. 5 is a diagram illustrating the operation of a second pump control circuit and a second charge pump.

In FIGS. 4 and 5, the operations of first to fourth pump control circuits 1110 to 1410 and first to fourth charge pumps 1120 to 1420, which are performed as the first memory die 1100 receives a command, will be described in detail below.

Referring to FIG. 4, the first memory die 1100 may include a first pump control circuit 1110 and a first charge pump 1120. The first pump control circuit 1110 may include a comparator 1111, an oscillator 1112, a first gate 1113, a second gate 1114, a third gate 1115, and a fourth gate 1116.

The first memory die 1100 may receive a command from a memory controller. The first memory die 1100 may activate (i.e., On) a pump enable signal PEN in response to the command.

The comparator 1111 may output an activated comparison signal until a pump voltage Vpmp received from the first charge pump 1120 becomes higher than a reference voltage VREF.

The oscillator 1112 may output an oscillation signal.

The first gate 1113 may output a first clock signal Clk1, as a first control signal Ct_sig1, based on the activated pump enable signal PEN(On), the activated comparison signal, and the oscillation signal. The first clock signal Clk1 may be output to the second gate 1114 and the fourth gate 1116.

The second gate 1114 may output a second clock signal Clk2 that is an inverted signal of the first clock signal as an operation alarm signal Alarm_sig. The second clock signal Clk2 may be output to the second to fourth pump control circuits 1210 to 1410 through a control line Ctrl_Line. The first to fourth pump control circuits 1110 to 1410 may be coupled to each other in common through the control line Ctrl_Line. The second clock signal Clk2 may be output to the third gate 1115.

The third gate 1115 may output a second control signal based on an inverted signal of the activated pump enable signal PEN(On), that is, a deactivated pump enable signal, and the second clock signal Clk2. The third gate 115 may output an activated second control signal Ct_sig2(high).

The fourth gate 1116 may output, as a pump operation signal Pmp_sig, a third clock signal Clk3 that is an inverted signal of the first clock signal based on the first clock signal Clk1 and the activated second control signal Ct_sig2(high). The third clock signal Clk3 may be output to the first charge pump 1120.

The first charge pump 1120 may perform a pump operation of generating the pump voltage Vpmp in response to the third clock signal Clk3. The pump voltage Vpmp may be output through a pump line Pmp_Line. The first to fourth charge pumps 1120 to 1420 may be coupled to each other in common through the pump line Pmp_Line. The pump voltage Vpmp may be output to the comparator 1111.

Next, referring to FIG. 5, the second memory die 1200 may include a second pump control circuit 1210 and a second charge pump 1220. The second pump control circuit 1210 may include a comparator 1211, an oscillator 1212, a first gate 1213, a second gate 1214, a third gate 1215, and a fourth gate 1216.

Because the second memory die 1200 has received no commands, a pump enable signal PEN may be in an inactive state (i.e., Off).

The comparator 1211 may output an activated comparison signal until a pump voltage Vpmp received from the second charge pump 1220 becomes higher than a reference voltage VREF.

The oscillator 1212 may output an oscillation signal.

The first gate 1213 may output a first control signal based on a deactivated pump enable signal PEN(Off), the activated comparison signal, and the oscillation signal. The first gate 1213 may output an activated first control signal Ct_sig(high). The activated first control signal Ct_sig(high) may be output to the second gate 1214 and the fourth gate 1216.

The second gate 1214 may float because the pump enable signal is in a deactivated state. The second gate 1214 might not output the activated first control signal Ct_sig(high) received from the first gate 1213.

The third gate 1215 may receive the second clock signal Clk2 output from the first pump control circuit 1110 through a control line Ctrl_Line. The third gate 1215 may output, as the second control signal Ct_sig2, a fourth clock signal Clk4 that is an inverted signal of the second clock signal based on an inverted signal of the deactivated pump enable signal PEN(Off), that is, the activated pump enable signal, and the second clock signal Clk2.

The fourth gate 1216 may output, as the pump operation signal Pmp_sig, a fifth clock signal Clk5 that is an inverted signal of the fourth clock signal Clk4, based on the activated first control signal Ct_sig1(high)) and the second control signal Ct_sig2(Clk4). The fifth clock signal Clk5 may be output to the second charge pump 1220.

The second charge pump 1220 may perform a pump operation of generating the pump voltage Vpmp in response to the fifth clock signal Clk5. The pump voltage Vpmp may be output through a pump line Pmp_Line. The pump voltage Vpmp may be output to the comparator 1211.

The third memory die 1300 may include a third pump control circuit 1310 and a third charge pump 1320. The fourth memory die 1400 may include a fourth pump control circuit 1410 and a fourth charge pump 1420. The third and fourth pump control circuits 1310 and 1410 may be operated in the same manner as the second pump control circuit 1210. The third and fourth charge pumps 1320 and 1420 may be operated in the same manner as the second charge pump 1220.

In detail, the third and fourth pump control circuits 1310 and 1410 may receive the second clock signal Clk2, output from the first pump control circuit 1110, through the control line Ctrl_Line. Each of the third and fourth pump control circuits 1310 and 1410 may output the fourth clock signal Clk4 that is an inverted signal of the second clock signal based on the inverted signal of the deactivated pump enable signal PEN(Off)) and the second clock signal Clk2. Each of the third and fourth pump control circuits 1310 and 1410 may output, as the pump operation signal Pmp_sig, the fifth clock signal Clk5 that is an inverted signal of the fourth clock signal, based on the activated first control signal Ct_sig1(high)) and the second control signal Ct_sig2(Clk4). Each of the third and fourth charge pumps 1320 and 1420 may perform a pump operation in response to the pump operation signal Pmp_sig. Each of the third and fourth charge pumps 1320 and 1420 may output the pump voltage Vpmp through the pump line Pmp_Line.

In an embodiment, the first pump control circuit 1110 may control the first charge pump 1120 to perform the pump operation based on the activated pump enable signal PEN(On) in response to the command received by the first memory die 1100. The first pump control circuit 1110 may output an operation alarm signal Alarm_sig, indicating that the first charge pump 1120 is operating, through the control line Ctrl_Line.

In an embodiment, the second to fourth pump control circuits 1210 to 1410 may receive the operation alarm signal Alarm_sig output from the first pump control circuit 1110. Because the second to fourth memory dies 1200 to 1400 have received no commands, the second to fourth pump control circuits 1210 to 1410 may receive the deactivated pump enable signal PEN(Off). The second to fourth pump control circuits 1210 to 1410 may control the second to fourth charge pumps 1220 to 1420, respectively, to perform the pump operation in response to the operation alarm signal Alarm_sig. The first to fourth charge pumps 1120 to 1420 may output the pump voltage through the pump line coupled in common thereto.

In an embodiment, assuming that only the first charge pump 1120 performs a pump operation when the first memory die 1100 receives a command, the first charge pump 1120 needs to be able to output the maximum current to generate the pump voltage. However, in accordance with an embodiment of the present disclosure, the second to fourth pump control circuits 1210 to 1410 may drive the second to fourth charge pumps 1220 to 1420 in response to the operation alarm signal Alarm_sig output from the first pump control circuit 1110. That is, in an embodiment, in compliance with the command received by the first memory die 1100, the first to fourth charge pumps 1120 to 1420 may perform the pump operation. However, in an embodiment, because the first to fourth charge pumps 1120 to 1420 output the pump voltage Vpmp through the pump line Pmp_Line coupled in common thereto, a low current may be output compared to the case where only the first charge pump 1120 performs the pump operation. Each of the first to fourth charge pumps 1120 to 1420 may output a low current proportional to the number of charge pumps coupled in common to the pump line Pmp_Line. In an embodiment, because fourth charge pumps included in different memory dies are coupled in common to the pump line Pmp_Line, each of the first to fourth charge pumps 1120 to 1420 may output only a current reduced to ¼ of the maximum current. In an embodiment, because each of the first to fourth charge pumps 1120 to 1420 may output the reduced current compared to the maximum current, the first to fourth charge pumps 1120 to 1420 may have a reduced area.

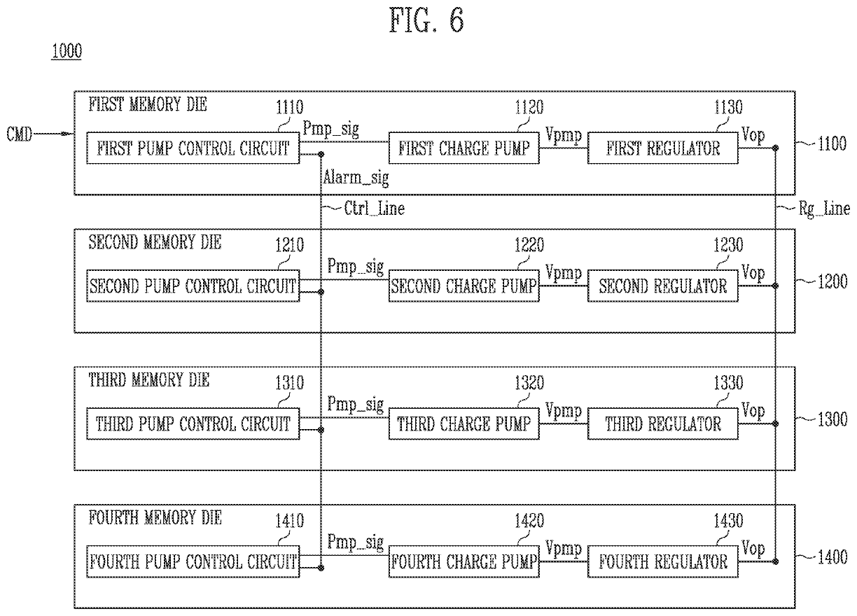

FIG. 6 is a diagram illustrating a plurality of memory dies, each including a pump control circuit, a charge pump, and a regulator.

Referring to FIG. 6, first to fourth memory dies 1100 to 1400 may include first to fourth pump control circuits 1110 to 1410, respectively, first to fourth charge pumps 1120 to 1420, respectively, and first to fourth regulators 1130 to 1430, respectively. The first to fourth pump control circuits 1110 to 1410 may be coupled to each other in common through a control line Ctrl_Line. The first to fourth regulators 1130 to 1430 may be coupled to each other in common through a regulator line Rg_Line.

In an embodiment, when the first memory die 1100 receives a command CMD, the first pump control circuit 1110 may output a pump operation signal Pmp_sig instructing the first charge pump 1120 to perform a pump operation in response to an activated pump enable signal. The first pump control circuit 1110 may output an operation alarm signal Alarm_sig through the control line Ctrl_Line.

The first charge pump 1120 may perform a pump operation of generating a pump voltage Vpmp in response to the pump operation signal Pmp_sig. The first charge pump 1120 may output the pump voltage to the first regulator 1130. The first regulator 1130 may generate an operating voltage Vop obtained by regulating the pump voltage Vpmp. The operating voltage Vop may be a voltage used to perform an operation corresponding to the command. In an embodiment, when the operation corresponding to the command is a program operation, the operating voltage Vop may be a program voltage or a program pass voltage. In an embodiment, when the operation corresponding to the command is a read operation, the operating voltage Vop may be a read voltage or a read pass voltage. The first regulator 1130 may output the operating voltage Vop through the regulator line Rg_Line.

The second to fourth pump control circuits 1210 to 1410 may receive the operation alarm signal Alarm_sig through the control line Ctrl_Line. The second to fourth pump control circuits 1210 to 1410 may output the pump operation signal Pmp_sig to the second to fourth charge pumps 1220 to 1420, respectively, in response to the operation alarm signal Alarm_sig. Each of the second to fourth charge pumps 1220 to 1420 may perform the pump operation of generating the pump voltage Vpmp in response to the pump operation signal Pmp_sig. The second to fourth charge pumps 1220 to 1420 may output the pump voltage Vpmp to the second to fourth regulators 1230 to 1430, respectively. Each of the second to fourth regulators 1230 to 1430 may generate the operating voltage Vop obtained by regulating the pump voltage Vpmp. Each of the second to fourth regulators 1230 to 1430 may output the operating voltage Vop through the regulator line Rg_Line.

In an embodiment, each of the first to fourth regulators 1130 to 1430 may output the operating voltage Vop through the regulator line Rg_Line coupled in common thereto in response to the command CMD received by the first memory die 1100. In FIG. 6, in an embodiment, the first to fourth regulators 1130 to 1430 output the operating voltage Vop through the regulator line Rg_Line, and thus a low current may be output compared to the case where only the first regulator 1130 outputs the operating voltage Vop.

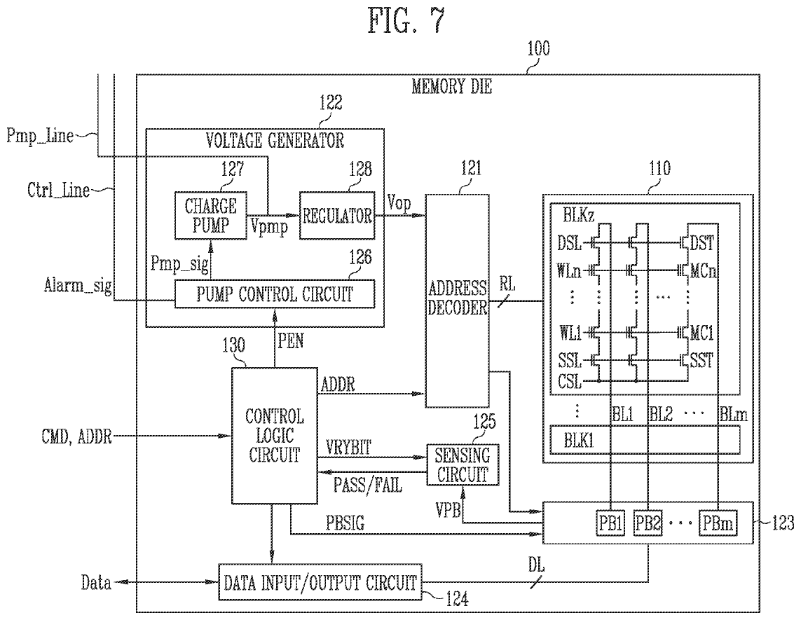

FIG. 7 is a diagram illustrating any one of a plurality of memory dies.

The memory die 100 illustrated in FIG. 7 may be any one of the first to fourth memory dies 1100 to 1400 illustrated in FIG. 1.

Referring to FIG. 7, the memory die 100 may include a memory cell array 110, a peripheral circuit, and a control logic circuit 130. The peripheral circuit may include an address decoder 121, a voltage generator 122, a page buffer group 123, a data input/output circuit 124, and a sensing circuit 125.

The memory cell array 110 may include a plurality of memory blocks BLK1 to BLKz. The plurality of memory blocks BLK1 to BLKz may be coupled to the address decoder 121 through row lines RL. The plurality of memory blocks BLK1 to BLKz may be coupled to the page buffer group 123 through bit lines BL1 to BLm. Each of the memory blocks BLK1 to BLKz may include a plurality of memory cells. In an embodiment, the plurality of memory cells may be nonvolatile memory cells.

Each of the memory cells may be implemented as a single-level cell (SLC) capable of storing one bit of data, a multi-level cell (MLC) capable of storing two bits of data, a triple-level cell (TLC) capable of storing three bits of data, a quad-level cell (QLC) capable of storing four bits of data, or a memory cell capable of storing five or more bits of data.

In an embodiment, any one memory block BLKz, among the plurality of memory blocks BLK1 to BLKz, may include a plurality of word lines WL1 to WLn arranged in parallel between a drain select line DSL and a source select line SSL. The memory block BLKz may include a plurality of memory cell strings coupled between any one bit line and a common source line CSL. The bit lines BL1 to BLm may be coupled to the plurality of memory cell strings, respectively, and the common source line CSL may be coupled in common to the plurality of memory cell strings.

For example, the memory cell string may include a drain select transistor DST, a plurality of memory cells MC1 to MCn, and a source select transistor SST, which are connected in series between the common source line CSL and the first bit line BL1. One memory cell string may include at least one drain select transistor DST and at least one source select transistor SST.

A drain of the drain select transistor DST may be coupled to the first bit line BL1, and a source of the source select transistor SST may be coupled to the common source line CSL. The plurality of memory cells MC1 to MCn may be connected in series between the drain select transistor DST and the source select transistor SST. Gates of the source select transistors SST included in different memory cell strings may be coupled to the source select line SSL, gates of the drain select transistors DST included in different memory cell strings ST may be coupled to the drain select line DSL, and gates of the memory cells MC1 to MCn may be coupled to the plurality of word lines WL1 to WLn, respectively.

The address decoder 121 may be coupled to the memory cell array 110 through the row lines RL. The row lines RL may include drain select lines, dummy word lines, the plurality of word lines, and source select lines.

The address decoder 121 may be operated in response to the control of the control logic circuit 130. The address decoder 121 may receive addresses ADDR from the control logic circuit 130.

The address decoder 121 may decode a block address among the received addresses ADDR. The address decoder 121 may select at least one of the memory blocks BLK1 to BLKz according to the decoded block address. The address decoder 121 may decode a row address among the received addresses ADDR. The address decoder 121 may select at least one word line of the selected memory block by applying an operating voltage Vop supplied from the voltage generator 122 to the at least one word line according to the decoded row address.

During a program operation, the address decoder 121 may apply a program voltage to the selected word line and apply a pass voltage having a level lower than that of the program voltage to unselected word lines. During a program verify operation, the address decoder 121 may apply a verify voltage to the selected word line and apply a verify pass voltage having a level higher than that of the verify voltage to the unselected word lines.

During a read operation, the address decoder 121 may apply a read voltage to the selected word line and apply a read pass voltage having a level higher than that of the read voltage to unselected word lines.

The address decoder 121 may decode a column address among the received addresses ADDR. The decoded column address may be transferred to the page buffer group 123. For example, the address decoder 121 may include components such as a row decoder, a column decoder, and an address buffer.

The voltage generator 122 may generate the operating voltage Vop using an external supply voltage that is supplied to the memory die 100. The voltage generator 122 may be operated under the control of the control logic circuit 130.

In an embodiment, the voltage generator 122 may include a pump control circuit 126, a charge pump 127, and a regulator 128. The pump control circuit 126 may drive the charge pump 127 in response to a pump enable signal PEN received from the control logic circuit 130. When the pump enable signal PEN is activated, the pump control circuit 126 may provide a pump operation signal Pmp_sig for performing a pump operation to the charge pump 127.

The pump control circuit 126 may be coupled in common to pump control circuits included in other memory dies through a control line Ctrl_Line. The pump control circuit 126 may output or receive an operation alarm signal Alarm_sig through the control line Ctrl_Line. The pump control circuit 126 may output the operation alarm signal Alarm_sig through the control line Ctrl_Line in response to the activated pump enable signal Ctrl_Line. The pump control circuit 126 may provide the pump operation signal Pmp_sig to the charge pump 127 in response to the operation alarm signal Alarm_sig received through the control line Ctrl_Line. The pump control circuit 126 illustrated in FIG. 7 may be implemented in the same manner as the first pump control circuit 1110 illustrated in FIG. 2.

The charge pump 127 may perform a pump operation of generating a pump voltage Vpmp in response to the pump operation signal Pmp_sig. The charge pump 127 may be coupled in common to charge pumps included in other memory dies through a pump line Pmp_Line. The charge pump 127 may output the pump voltage Vpmp through the pump line Pmp_Line. The charge pump 127 may output the pump voltage Vpmp to the regulator 128.

The regulator 128 may generate the operating voltage Vop obtained by regulating the pump voltage Vpmp. The regulator 128 may provide the operating voltage Vop to the address decoder 121. For example, the regulator 128 may generate a plurality of erase voltages, a plurality of program voltages, a plurality of pass voltages, a plurality of select read voltages, and a plurality of unselect read voltages. The generated operating voltage Vop may be supplied to the memory cell array 110 by the address decoder 121.

The page buffer group 123 may include first to m-th page buffers PB1 to PBm. The first to m-th page buffers PB1 to PBm may be coupled to the memory cell array 110 through the first to m-th bit lines BL1 to BLm, respectively. The first to m-th page buffers PB1 to PBm may be operated under the control of the control logic circuit 130.

The first to m-th page buffers PB1 to PBm may transmit/receive data DATA to/from the data input/output circuit 124. During a program operation, the first to m-th page buffers PB1 to PBm may receive data DATA through the data input/output circuit 124 and data lines DL.

During a program operation, the first to m-th page buffers PB1 to PBm may transfer the data DATA, received through the data input/output circuit 124, to selected memory cells through the bit lines BL1 to BLm. The memory cells in the selected page may be programmed based on the received data DATA. Memory cells coupled to a bit line to which a program-enable voltage (e.g., a ground voltage) is applied may have increased threshold voltages. The threshold voltages of memory cells coupled to a bit line to which a program-inhibit voltage (e.g., a supply voltage) is applied may be maintained. During a verify operation, the first to m-th page buffers PB1 to PBm may read the data DATA stored in the selected memory cells from the selected memory cells through the bit lines BL1 to BLm.

During a read operation, the page buffer group 123 may sense data from memory cells coupled to the selected word line through the bit lines BL1 to BLm, and may store the sensed data in the first to m-th page buffers PB1 to PBm.

The data input/output circuit 124 may be coupled to the first to m-th page buffers PB1 to PBm through the data lines DL. The data input/output circuit 124 may be operated under the control of the control logic circuit 130.

The data input/output circuit 124 may include a plurality of input/output buffers (not illustrated) which receive input data DATA. During a program operation, the data input/output circuit 124 may receive the data DATA to be stored from the memory controller. During the read operation, the data input/output circuit 124 may output the sensed data stored in the first to m-th page buffers PB1 to PBm to the memory controller.

During a verify operation, the sensing circuit 125 may generate a reference current in response to an enable bit signal VRYBIT generated by the control logic circuit 130, and may output a pass signal or a fail signal to the control logic circuit 130 by comparing a sensing voltage VPB received from the page buffer group 123 with a reference voltage generated by the reference current. In an example, the sensing circuit 125 may output the pass signal to the control logic circuit 130 when the magnitude of the sensing voltage VPB is less than that of the reference voltage. In an example, the sensing circuit 125 may output a fail signal to the control logic circuit 130 when the magnitude of the sensing voltage VPB is greater than that of the reference voltage.

The control logic circuit 130 may be coupled to the address decoder 121, the voltage generator 122, the page buffer group 123, the data input/output circuit 124, and the sensing circuit 125. The control logic circuit 130 may control the overall operation of the memory device 100. The control logic circuit 130 may be operated in response to a command CMD received from the memory controller.

The control logic circuit 130 may control the peripheral circuit by generating various types of signals in response to the command CMD and an address ADDR. For example, the control logic circuit 130 may generate the pump enable signal PEN, the addresses ADDR, a page buffer control signal PBSIG, and the enable bit signal VRYBIT in response to the command CMD and the address ADDR. The control logic circuit 130 may output the pump enable signal PEN to the voltage generator 122, may output the addresses ADDR to the address decoder 121, may output the page buffer control signal PBSIG to the page buffer group 123, and may output the enable bit signal VRYBIT to the sensing circuit 125.

In an embodiment, the control logic circuit 130 may activate the pump enable signal PEN in response to the command CMD. In an embodiment, when the command CMD is not received, the pump enable signal PEN may be in a deactivated state.

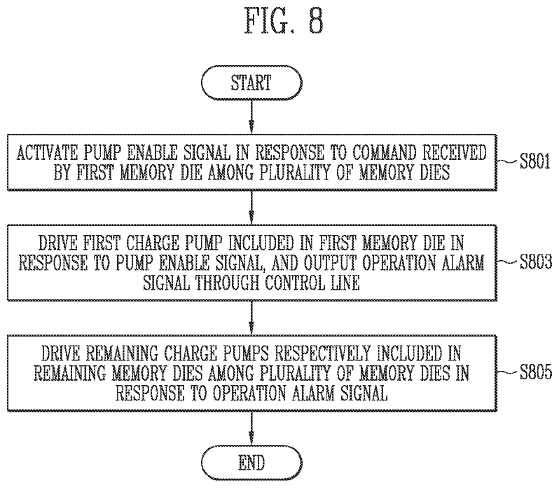

FIG. 8 is a flowchart illustrating a pump operation performed by a plurality of charge pumps.

Referring to FIG. 8, at step S801, a first memory die among a plurality of memory dies included in a memory device 1000 may activate a pump enable signal in response to a command received by the first memory die.

At step S803, the first memory die may drive a first charge pump included in the first memory die in response to the pump enable signal, and may output an operation alarm signal through a control line.

At step S805, the remaining memory dies, other than the first memory die among the plurality of memory dies, may drive the remaining charge pumps respectively included in the remaining memory dies in response to the operation alarm signal. The first charge pump and the remaining charge pumps may perform the pump operation of generating the pump voltage.

According to an embodiment of the present disclosure, there is provided a memory device for driving charge pumps having a reduced area.

What is claimed is:

1. A memory device, comprising:
a first memory die including a first charge pump and a first pump control circuit; and
a second memory die including a second charge pump coupled to the first charge pump through a pump line and a second pump control circuit coupled to the first pump control circuit through a control line,
wherein the first pump control circuit is configured to control the first charge pump to perform a pump operation of generating a pump voltage in response to a command received by the first memory die, and is configured to output an operation alarm signal through the control line, and
wherein the second pump control circuit is configured to control the second charge pump to perform the pump operation in response to the operation alarm signal.

2. The memory device according to claim 1, wherein each of the first charge pump and the second charge pump outputs the pump voltage to the pump line.

3. The memory device according to claim 1, wherein:
the first memory die further comprises a first control logic circuit configured to activate a pump enable signal in response to the command, the first control logic circuit coupled to the first pump control circuit, and
the first pump control circuit configured to provide a pump operation signal instructing the pump operation to be performed by the first charge pump in response to an activated pump enable signal.

4. The memory device according to claim 1, wherein:
the second memory die further comprises a second control logic circuit configured to provide a deactivated pump enable signal to the second pump control circuit, and
the second pump control circuit configured to provide a pump operation signal instructing the pump operation to be performed by the second charge pump based on the deactivated pump enable signal and the operation alarm signal.

5. The memory device according to claim 1, wherein each of the first pump control circuit and the second pump control circuit comprises:
a comparator configured to output a comparison signal obtained by comparing a reference voltage with the pump voltage output from the first charge pump or the second charge pump;
a first gate configured to output a first control signal based on the comparison signal, the pump enable signal, and an oscillation signal received from an oscillator;
a second gate configured to output the operation alarm signal based on the first control signal and the pump enable signal;
a third gate configured to output a second control signal based on the operation alarm signal and the pump enable signal; and
a fourth gate configured to provide a pump operation signal to the first charge pump or the second charge pump based on the first control signal and the second control signal.

6. The memory device according to claim 5, wherein:
the first gate of the first pump control circuit outputs, as the first control signal, a first clock signal based on an activated pump enable signal,
the second gate of the first pump control circuit outputs, as the operation alarm signal, a second clock signal that is an inverted signal of the first clock signal based on the activated pump enable signal,
the third gate of the first pump control circuit outputs an activated second control signal based on the activated pump enable signal, and
the fourth gate of the first pump control circuit outputs, as the pump operation signal, a third clock signal that is an inverted signal of the first clock signal to the first charge pump based on the first clock signal and the activated second control signal.

7. The memory device according to claim 5, wherein:
the first gate of the second pump control circuit outputs an activated first control signal based on a deactivated pump enable signal,
the second gate of the second pump control circuit floats the operation alarm signal based on the deactivated pump enable signal,
the third gate of the second pump control circuit outputs a fourth clock signal as the second control signal based on the operation alarm signal, and
the fourth gate of the second pump control circuit outputs, as the pump operation signal, a fifth clock signal that is an inverted signal of the fourth clock signal to the second charge pump based on the activated first control signal and the fourth clock signal.

8. The memory device according to claim 1, wherein the first memory die further comprises:
a regulator configured to regulate the pump voltage as an operating voltage; and
an address decoder configured to provide the operating voltage to at least one word line.

9. A memory device, comprising:
a first memory die including a first pump control circuit, a first charge pump, and a first regulator; and
a second memory die including a second pump control circuit coupled in common to the first pump control circuit, a second charge pump, and a second regulator coupled in common to the first regulator,
wherein the first pump control circuit drives the first charge pump based on a pump enable signal activated in response to a command received by the first memory die, and outputs an operation alarm signal, indicating that the first charge pump is operating, to the second pump control circuit, and
wherein the second pump control circuit drives the second charge pump in response to the operation alarm signal.

10. The memory device according to claim 9, wherein:
each of the first charge pump and the second charge pump performs a pump operation of generating a pump voltage, and
each of the first regulator and the second regulator outputs an operating voltage obtained by regulating the pump voltage to a regulator line coupled in common to the first and second regulators.

11. The memory device according to claim 9, wherein the first memory die further comprises:
a first control logic circuit configured to activate the pump enable signal in response to the command received from a memory controller.

12. The memory device according to claim 9, wherein the second pump control circuit receives a deactivated pump enable signal.

13. The memory device according to claim 9, wherein the first pump control circuit comprises:
a comparator configured to output a comparison signal obtained by comparing a reference voltage with a pump voltage output from the first charge pump;
a first gate configured to output a first clock signal based on the comparison signal, the activated pump enable signal, and an oscillation signal received from an oscillator;
a second gate configured to output, as the operation alarm signal, a second clock signal that is an inverted signal of the first clock signal based on the first clock signal and the activated pump enable signal;
a third gate configured to output an activated first control signal based on the operation alarm signal and the activated pump enable signal; and
a fourth gate configured to output, as a pump operation signal, a third clock signal that is an inverted signal of the first clock signal to the first charge pump based on the first clock signal and the activated first control signal.

14. The memory device according to claim 9, wherein the second pump control circuit comprises:
a comparator configured to output a comparison signal obtained by comparing a reference voltage with a pump voltage output from the second charge pump;
a first gate configured to output an activated second control signal based on the comparison signal, a deactivated pump enable signal, and an oscillation signal received from an oscillator;
a second gate configured to float the operation alarm signal based on the activated second control signal and the deactivated pump enable signal;
a third gate configured to output a fourth clock signal based on the deactivated pump enable signal and the operation alarm signal; and
a fourth gate configured to output, as a pump operation signal, a fifth clock signal that is an inverted signal of the fourth clock signal to the second charge pump based on the activated second control signal and the fourth clock signal.

15. The memory device according to claim 10, wherein the first memory die performs an operation corresponding to the command based on the operating voltage.

16. A memory device, comprising:
a plurality of charge pumps coupled to each other in common through a pump line; and
a plurality of pump control circuits coupled to each other in common through a control line, and configured to control respective pump operations of the plurality of charge pumps,
wherein a first pump control circuit among the plurality of pump control circuits controls a first charge pump among the plurality of charge pumps to perform the pump operation in response to a pump enable signal, and outputs an operation alarm signal to the control line,
wherein remaining pump control circuits among the plurality of pump control circuits control remaining charge pumps among the plurality of charge pumps to perform respective pump operations in response to the operation alarm signal, and
wherein the plurality of charge pumps and the plurality of pump control circuits are included in different memory dies, respectively.

17. The memory device according to claim 16, wherein the pump enable signal is activated in response to a command received by a memory die including the first pump control circuit and the first charge pump.

18. The memory device according to claim 16, wherein a pump enable signal coupled to each of the remaining pump control circuits is in a deactivated state.

19. The memory device according to claim 16, wherein the first pump control circuit comprises:
a comparator configured to output a comparison signal obtained by comparing a reference voltage with a pump voltage output from the first charge pump;
a first gate configured to output a first clock signal based on the comparison signal, an activated pump enable signal, and an oscillation signal received from an oscillator;
a second gate configured to output, as the operation alarm signal, a second clock signal that is an inverted signal of the first clock signal based on the first clock signal and the activated pump enable signal;
a third gate configured to output an activated first control signal based on the operation alarm signal and the activated pump enable signal; and
a fourth gate configured to output, as a pump operation signal, a third clock signal that is an inverted signal of the first clock signal to the first charge pump based on the first clock signal and the activated first control signal.

20. The memory device according to claim 16, wherein each of the remaining pump control circuits comprises:
a comparator configured to output a comparison signal obtained by comparing a reference voltage with a pump voltage output from any one of the remaining charge pumps;
a first gate configured to output an activated second control signal based on the comparison signal, a deactivated pump enable signal, and an oscillation signal received from an oscillator;
a second gate configured to float the operation alarm signal based on the activated second control signal and the deactivated pump enable signal;
a third gate configured to output a fourth clock signal based on the deactivated pump enable signal and the operation alarm signal; and
a fourth gate configured to output, as a pump operation signal, a fifth clock signal that is an inverted signal of the fourth clock signal to the one charge pump based on the activated second control signal and the fourth clock signal.
